(19) United States
(12) Patent Application Publication
(10) Pub. No.: US 2025/0308943 A1
(43) Pub. Date: Oct. 2, 2025

(54) GAS SUPPLY SYSTEM AND METHOD

(71) Applicant: KC CO., LTD., Gyeonggi-do (KR)

(72) Inventors: Ken Jun JUNG, Gyeonggi-do (KR); Jong Chan KIM, Gyeonggi-do (KR); Du Seok LEE, Gyeonggi-do (KR)

(73) Assignee: KC CO., LTD., Gyeonggi-do (KR)

(21) Appl. No.: 19/087,612

(22) Filed: Mar. 24, 2025

(30) Foreign Application Priority Data
Mar. 28, 2024 (KR) 10-2024-0042636

(51) Int. Cl. H01L 21/67

(52) U.S. Cl. CPC H01L 21/67017

(57) ABSTRACT

A gas supply system is provided. The gas supply system includes a supply line configured to connect a gas container to a process object, a purge line connected to a first point of the supply line and connected to a purge gas supply portion configured to supply a purge gas, a first exhaust line connected to a second point of the supply line and connecting the supply line to an exhaust portion configured to apply negative pressure, and a second exhaust line connected to a third point of the purge line and connecting the purge line to a fourth point of the first exhaust line. The first point of the supply line is closer to the gas container than the second point is.

### CROSS-REFERENCE TO RELATED APPLICATION

This application claims the benefit of Korean Patent Application No. 10-2024-0042636 filed on Mar. 28, 2024, in the Korean Intellectual Property Office, the entire disclosure of which is incorporated herein by reference for all purposes.

### BACKGROUND

### 1. Field of the Invention

One or more embodiments relate to a gas supply system and method.

### 2. Description of the Related Art

Typically, during the semiconductor or electronic device manufacturing process, various types of gases may be supplied. During the process of replacing gas containers after using gas for the manufacture of semiconductors or electronic devices, moisture may be contained in a purge gas when purging a supply pipe. This moisture may be absorbed into the supply pipe and react with a corrosive gas when the purge gas is supplied, corroding the supply pipe. Therefore, a process is needed to remove moisture contained in the purge gas.

A conventional purge method is performed by repeating a process of introducing the purge gas into a gas line to dilute gas concentration and applying negative pressure to the gas line to discharge the purge gas. In this case, when introducing the purge gas, moisture among impurities in the purge gas may repeatedly flow into the pipe and be adsorbed on the pipe or parts, causing corrosion or a failure of components. Thus, there is a need for a purge method or a gas supply system equipped with a purge system to resolve this.

The above description is information the inventor(s) acquired during the course of conceiving the present disclosure, or already possessed at the time, and is not necessarily art publicly known before the present application was filed.

### SUMMARY

Embodiments provide a gas supply system for performing a purge process that prevents corrosion of a gas line and/or a failure of components.

Embodiments provide a gas supply method for performing a purge process that prevents corrosion of a gas line and/or a failure of components.

According to an aspect, there is provided a gas supply system including a supply line configured to connect a gas container to a process object, a purge line connected to a first point of the supply line and connected to a purge gas supply portion configured to supply a purge gas, a first exhaust line connected to a second point of the supply line and connecting the supply line to an exhaust portion configured to apply negative pressure, and a second exhaust line connected to a third point of the purge line and connecting the purge line to a fourth point of the first exhaust line.

The first point of the supply line may be closer to the gas container than the second point is, and the supply line may be connected to a supply pressure sensor configured to detect a pressure within the supply line and a first supply valve configured to control a flow of a fluid flowing through the supply line.

The purge line may be connected to a first purge valve connected to a point between the first point and the third point and configured to control a flow of a fluid flowing through the purge line, a second purge valve disposed between the first purge valve and the third point and configured to control the flow of the fluid flowing through the purge line, a purge pressure sensor disposed between the first purge valve and the second purge valve and configured to detect a pressure within the purge line, a first regulator disposed between the third point and the purge gas supply portion and configured to control the pressure within the purge line, and a flow rate control device disposed between the first regulator and the third point.

The first exhaust line may be connected to a first exhaust valve disposed between the second point and the fourth point and a second exhaust valve disposed between the fourth point and the exhaust portion, and the second exhaust line may be connected to a third exhaust valve configured to control gas supply and an exhaust pressure sensor disposed between the third exhaust valve and the fourth point and configured to detect a pressure within a line.

The purge line may be connected to a first purge valve connected to a point between the first point and the third point and configured to control a flow of a fluid flowing through the purge line, a fourth purge valve disposed between the third point and the purge gas supply portion and configured to control the flow of the fluid flowing through the purge line, a purge pressure sensor disposed between the first purge valve and the fourth purge valve and configured to detect a pressure within the purge line, a first regulator disposed between the fourth purge valve and the purge gas supply portion and configured to control the pressure within the purge line, and a flow rate control device disposed between the first regulator and the fourth purge valve.

The supply line may be further connected to a second regulator configured to control a pressure of the supply line.

The supply line may be further connected to a second supply valve configured to control a flow within the supply line.

The supply line may be further connected to a supply filter.

The first exhaust line may be further connected to a first exhaust valve disposed between the second point and the fourth point.

The purge line may be further connected to a fourth purge valve connected to a rear end of the flow rate control device.

According to an aspect, there is provided a gas supply method through a gas supply system including opening a second exhaust valve, continuously applying, by an exhaust portion, negative pressure, opening a first exhaust valve and a second supply valve, opening a third exhaust valve and a second purge valve, closing the third exhaust valve and opening a first purge valve, and repeatedly opening and closing a fourth purge valve.

The gas supply method may further include, after opening the second exhaust valve, detecting, using the exhaust pressure sensor, whether there is a vacuum.

The gas supply method may further include detecting, using the exhaust pressure sensor, whether there is a vacuum, and closing the first exhaust valve or all valves, when a pressure change range is less than or equal to a preset value for a determined period of time.

The gas supply method may further include venting a second exhaust line, with the first purge valve closed.

The gas supply method may further include venting a first exhaust line.

According to an aspect, there is provided a gas supply method through a gas supply system including providing the gas supply system with all valves closed, venting a first exhaust line and a supply line while a first supply valve, a fourth purge valve, and a first purge valve are closed, exhausting a second exhaust line and a purge line to a vacuum state, and closing the second exhaust line and performing a pulse vent, using a flow rate control device and the fourth purge valve of the purge line, between a first pressure and a second pressure.

The first pressure may be a pressure that causes a Knudsen number according to a diameter of a pipe to be less than 1, and the second pressure may be a pressure less than or equal to a saturated vapor pressure of water in the pipe to cause water molecules within the pipe to evaporate.

Additional aspects of embodiments will be set forth in part in the description which follows and, in part, will be apparent from the description, or may be learned by practice of the disclosure.

According to embodiments, the gas supply system and method may purge a process line with a purge gas before and after injecting a processing gas through an inside of the process line.

According to embodiments, the gas supply system and method may reduce or prevent influx of impurities when injecting a purge gas.

According to embodiments, the gas supply system and method may reduce or prevent corrosion of a line that may occur when a purge process is repeatedly performed.

According to embodiments, the gas supply system and method may maximize a purge effect by configuring a purge valve and an exhaust valve connected to a process line in a single row without a stagnant section.

The effects of the gas supply system and the gas supply method according to embodiments are not limited to the above-mentioned effects, and other unmentioned effects may be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram schematically illustrating a gas supply system according to an embodiment; and

FIG. 2 is a diagram schematically illustrating a gas supply system according to a related art.

### DETAILED DESCRIPTION

Hereinafter, embodiments of the present disclosure are described in detail with reference to the accompanying drawings. Regarding the reference numerals assigned to the components in the drawings, it should be noted that the same components are designated by the same reference numerals, wherever possible, even though they are shown in different drawings. Also, in the description of the embodiments, detailed description of well-known related structures or functions is omitted when it is deemed that such description will cause in ambiguous interpretation of the present disclosure.

Also, in the description of the components of the embodiments, terms such as first, second, A, B, (a), (b), and the like may be used. These terms are used only for the purpose of discriminating one component from another component, and the nature, the sequences, or the orders of the components are not limited by the terms. It is to be understood that if a component is described as being “connected,” “coupled,” or “joined” to another component, the former may be directly “connected,” “coupled,” or “joined” to the latter or “connected,” “coupled,” or “joined” to the latter via another component.

The same name may be used to describe components having a common function in different embodiments. Unless otherwise mentioned, the description of one embodiment may be applicable to another embodiment. Thus, duplicated description is omitted for conciseness.

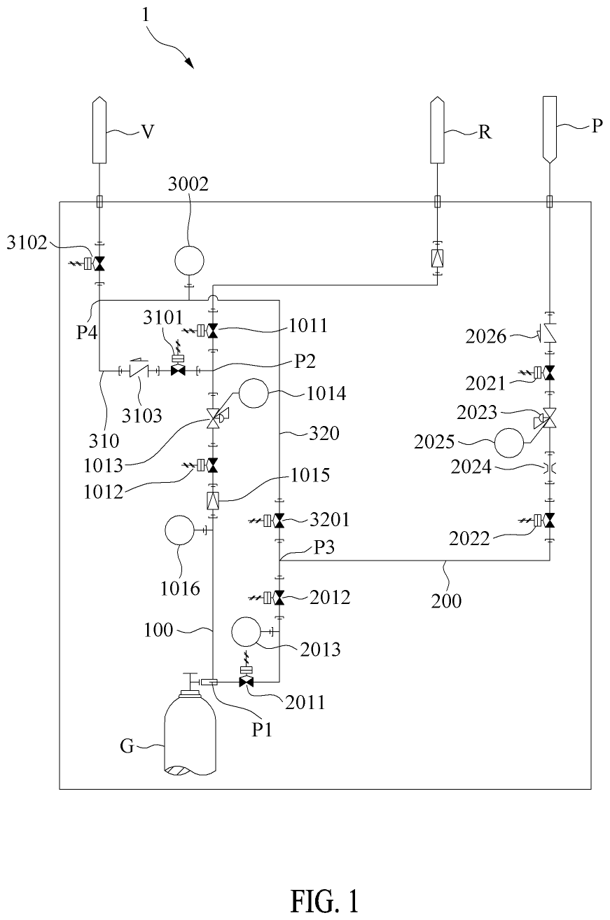

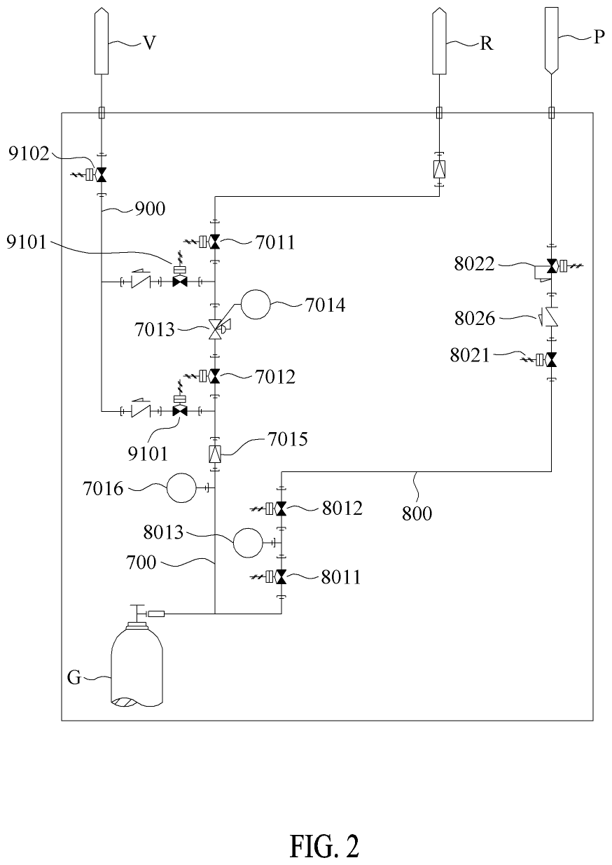

FIG. 1 is a diagram schematically illustrating a gas supply system 1 according to an embodiment, and FIG. 2 is a diagram schematically illustrating a gas supply system according to a related art.

Referring to FIG. 1, the gas supply system 1 may receive a processing gas from a gas container G and supply the processing gas to a process target R. In an embodiment, the gas supply system 1 may allow gas to flow along a predetermined flow path inside the gas supply system 1, control a flow of gas using a valve, and supply at least a portion of supplied gas to a supply target.

In an embodiment, the supply target may include a substrate used in a semiconductor process or semiconductor facility equipment including the same, or a display included in an electronic device. However, the supply target is not limited thereto and may include any target to which the processing gas may be supplied.

Hereinafter, when describing components included in the gas supply system 1, ‘front end’ and ‘rear end’ may be defined according to a flow direction of the processing gas. For example, ‘front end’ may refer to a point at which the processing gas flows in based on a flow path of the processing gas, and ‘rear end’ may refer to a point at which the processing gas flows out.

The gas supply system 1 according to an embodiment may include a supply line 100, a purge line 200, a first exhaust line 310, and a second exhaust line 320. In an embodiment, the supply line 100 may be connected to the purge line 200 at a first point P1 on the supply line 100. In an embodiment, the supply line 100 may be connected to the first exhaust line 310 at a second point P2 on the supply line 100. In an embodiment, the purge line 200 may be connected to the second exhaust line 320 at a third point P3 on the purge line 200. In an embodiment, the first exhaust line 310 may be connected to the second exhaust line 320 at a fourth point P4 on the first exhaust line 310. In other words, the first point P1 to the fourth point P4 may be points at which a line branches.

In an embodiment, the supply line 100 may provide a path for the processing gas to flow from the gas container G to the process target R. In an embodiment, the supply line 100 may include a pipe through which fluid may flow inside. In an embodiment, one end portion of the supply line 100 may be connected to the gas container G and an other end portion of the supply line 100 may be connected to the process target R. For example, the supply line 100 may connect the gas container G to the process target R so that the gas container G and the process target R may be in fluid communication with each other. In this case, the processing gas may flow from the gas container G into the supply line 100, flow from a front end to a rear end of the supply line 100, and be discharged toward the process target R.

In an embodiment, a supply pressure sensor 1016, a first supply valve 1011, a second supply valve 1012, a second regulator 1013, and a supply filter 1015 may be connected to the supply line 100.

In an embodiment, the supply pressure sensor 1016 may detect pressure due to the fluid within the supply line 100. For example, the supply pressure sensor 1016 may detect whether there is a vacuum within the supply line 100. In an embodiment, the supply pressure sensor 1016 may be connected to an arbitrary point in the supply line 100. For example, the supply pressure sensor 1016 may detect whether the supply line 100 is airtight when an inside of the supply line 100 is exhausted to a vacuum state.

In an embodiment, the first supply valve 1011 may control a flow of the fluid flowing through the supply line 100. In an embodiment, the first supply valve 1011 may be connected to the supply line 100. In an embodiment, the first supply valve 1011 may selectively open or close the supply line 100. For example, when the first supply valve 1011 is opened, the supply line 100 at a front end and a rear end of the first supply valve 1011 may be connected to be in fluid communication. In this case, the fluid may flow from the front end of the first supply valve 1011 to the rear end of the first supply valve 1011. For example, when the first supply valve 1011 is closed, the supply line 100 at the front end and the rear end of the first supply valve 1011 may be sealed and separated so that the fluid may not flow. In this case, the fluid may not flow from the front end of the first supply valve 1011 to the rear end of the first supply valve 1011. In other words, the supply line 100 may be separated starting from the first supply valve 1011 so that the fluid may not flow through the supply line 100. In an embodiment, the first supply valve 1011 may be connected to a rear end of the supply pressure sensor 1016. However, it should be noted that these connection locations are non-limiting examples, and modifications and alterations may be made thereto. In an embodiment, the first supply valve 1011 may partially open or partially close the supply line 100 between being open and closed. For example, when the first supply valve 1011 partially opens or partially closes the supply line 100, the supply line 100 may be in fluid communication starting from the first supply valve 1011. In this case, the fluid may flow relatively little compared to an open state.

In an embodiment, the second regulator 1013 may control pressure within the supply line 100. The second regulator 1013 may be connected to the supply line 100. The second regulator 1013 may control the pressure within the supply line 100 by regulating the pressure of the fluid flowing through the supply line 100. The second regulator 1013 may be located at the rear end of the supply pressure sensor 1016. The second regulator 1013 may be located at the front end of the first supply valve 1011. For example, the second regulator 1013 may regulate the flow of the fluid that is passing through the first supply valve 1011 and pressurizing. In this case, the pressure within the supply line 100 at a rear end of the second regulator 1013 may be controlled. However, it should be noted that these connection locations are non-limiting examples, and modifications and alterations may be made thereto. The supply filter 1015 may filter the fluid flowing within the supply line 100. The supply filter 1015 may be connected to a point on the supply line 100.

In an embodiment, the purge line 200 may provide a path for a purge gas to flow from a purge gas supply portion P to the supply line 100 to purge the inside of the supply line 100. One end portion of the purge line 200 may be connected to the purge gas supply portion P and an other end portion may be connected to the first point P1 of the supply line 100. Here, the first point P1 may be an arbitrary point on the supply line 100. For example, the first point P1 may be an arbitrary point adjacent to the gas container G in the supply line 100. In this case, the first point P1 may be positioned adjacent to the gas container G so that a dead space, in which the purge gas is not supplied to the supply line 100, may be minimized. For example, the purge line 200 may connect the purge gas supply portion P to the supply line 100 so that the purge gas supply portion P and the supply line 100 may be in fluid communication. In this case, the purge gas may flow from the purge gas supply portion P into the purge line 200 and may flow from a front end to a rear end of the purge line 200 and to the inside of the supply line 100.

In an embodiment, a first purge valve 2011, a second purge valve 2012, a third purge valve 2021, a purge pressure sensor 2013, a first regulator 2023, and a flow rate control device 2024 may be connected to the purge line 200. In addition, a fourth purge valve 2022 and a second check valve may further be connected to the purge line 200.

In an embodiment, the first purge valve 2011 may control a flow of a fluid flowing through the purge line 200. In addition, the first purge valve 2011 may be connected to the purge line 200. Furthermore, the first purge valve 2011 may selectively open or close the purge line 200. For example, when the first purge valve 2011 is opened, the purge line 200 at a front end and a rear end of the first purge valve 2011 may be connected to be in fluid communication. In this case, the fluid may flow from the front end of the first purge valve 2011 to the rear end of the first purge valve 2011. For example, when the first purge valve 2011 is closed, the purge line 200 at the front end and the rear end of the first purge valve 2011 may be sealed and separated so that the fluid may not flow. In this case, the fluid may not flow from the front end of the first purge valve 2011 to the rear end of the first purge valve 2011. In other words, the purge line 200 may be separated starting from the first purge valve 2011 so that the fluid may not flow through the purge line 200. In an embodiment, the first purge valve 2011 may be connected to a point between the first point P1 and the third point P3. Here, the third point P3 may refer to an arbitrary point on the purge line 200 to which the second exhaust line 320 described below may be connected. In this case, the first purge valve 2011 may control the flow of the fluid passing through the third point P3 and flowing toward the first point P1. However, it should be noted that these connection locations are non-limiting examples, and modifications and alterations may be made thereto. In an embodiment, the first purge valve 2011 may partially open or partially close the purge line 200 between being open and closed. For example, when the first purge valve 2011 partially opens or partially closes the purge line 200, the purge line 200 may be in fluid communication starting from the first purge valve 2011. In this case, only a little of the fluid may move compared to the open state.

In an embodiment, the second purge valve 2012 may control the flow of the fluid flowing through the purge line 200. When describing the second purge valve 2012, in order to avoid duplicate description, the description provided for the first purge valve 2011 may apply to a configuration that is substantially identical to the first purge valve 2011, to the extent not conflicting with the first purge valve 2011. The second purge valve 2012 may be disposed between the first purge valve 2011 and the third point P3. In this case, the second purge valve 2012 may control the flow of the fluid passing through the third point P3 and flowing through the purge line 200. However, it should be noted that these connection locations are non-limiting examples, and modifications and alterations may be made thereto. The second purge valve 2012 may be opened and closed independently of the first purge valve 2011.

In an embodiment, the third purge valve 2021 may control the flow of the fluid flowing through the purge line 200. When describing the third purge valve 2021, in order to avoid duplicate description, the description provided for the first purge valve 2011 may apply to a configuration that is substantially identical to the first purge valve 2011, to the extent not conflicting with the first purge valve 2011. The third purge valve 2021 may be disposed between the third point P3 and the purge gas supply portion P. In this case, the third purge valve 2021 may control the flow of the fluid flowing in from the purge gas supply portion P and flowing toward the rear end of the third purge valve 2021. However, it should be noted that these connection locations are non-limiting examples, and modifications and alterations may be made thereto. The third purge valve 2021 may be opened and closed independently of the first purge valve 2011 and the second purge valve 2012.

In an embodiment, the purge pressure sensor 2013 may detect pressure within the purge line 200. For example, the purge pressure sensor 2013 may detect whether an inside of the purge line 200 is in a vacuum state. The purge pressure sensor 2013 may be disposed between the first purge valve 2011 and the second purge valve 2012. For example, the purge pressure sensor 2013 may detect the pressure within the purge line 200 in a section between the first purge valve 2011 and the second purge valve 2012. However, it should be noted that these connection locations are non-limiting examples, and modifications and alterations may be made thereto.

In an embodiment, the first regulator 2023 may regulate the pressure within the purge line 200. For example, the first regulator 2023 may regulate a flow of the purge gas flowing within the purge line 200. In this case, the pressure within the purge line 200 may change according to the flow of the purge gas. The first regulator 2023 may be disposed between the third purge valve 2021 and the purge gas supply portion P. In this case, the purge gas that has passed through the third purge valve 2021 may pass through the first regulator 2023. In this case, the first regulator 2023 may control the pressure within the purge line 200 at a rear end of the first regulator 2023 by controlling the flow of the purge gas that has passed through the third purge valve 2021. However, it should be noted that these connection locations are non-limiting examples, and modifications and alterations may be made thereto.

In an embodiment, the flow rate control device 2024 may control a flow rate of the purge gas. For example, the flow rate control device 2024 may be connected to the purge line 200 to reduce the flow rate of the purge gas. For example, the flow rate control device 2024 may control the flow rate of the purge gas so that a trace amount of the purge gas may be injected into the purge line 200. For example, when the purge gas flows into the purge line 200, the flow rate control device 2024 may control the flow rate of the purge gas flowing into the purge line 200 so that pressure within a line may be managed to be less than or equal to saturated vapor pressure of water. In this case, the pressure within the line may be controlled to be less than or equal to the saturated vapor pressure of water through the first regulator 2023 as well as the flow rate control device 2024. In other words, the flow rate control device 2024 and the first regulator 2023 may together control the flow of the purge gas in the line, thereby managing the pressure in the line to be below the saturated vapor pressure of water. For example, the flow rate control device 2024 may be located between the third purge valve 2021 and the fourth purge valve 2022. In addition, the flow rate control device 2024 may be located at the front end of the first purge valve 2011 and the second purge valve 2012. In this case, a pulse vent may be performed by controlling the opening and closing of the first purge valve 2011 and the second purge valve 2012. For example, when the pressure within the line is lower than the saturated vapor pressure of water, active evaporation of moisture within the line may occur. In this case, the moisture evaporated within the line may be discharged outside the line. The flow rate control device 2024 may include a portion of the line having a smaller diameter than an inner diameter of the purge line 200. For example, the flow rate control device 2024 may include an orifice, a variable orifice, a mass flow controller (MFC), a bleed valve, a metering valve, or a flow meter. For example, a diameter of the flow rate control device 2024 may be 0.2 mm. However, this is an example, and the flow rate control device 2024 is not limited thereto. Also, it should be noted that one of ordinary skill in the art may make various modifications and variations to the embodiments described herein to control the flow rate of the purge gas.

In an embodiment, the fourth purge valve 2022 may control the flow of the fluid flowing through the purge line 200. When describing the fourth purge valve 2022, the description of the first purge valve 2011 may apply thereto, to the extent not conflicting with the first purge valve 2011. The fourth purge valve 2022 may control the flow of the fluid flowing toward the flow rate control device 2024. For example, when the fourth purge valve 2022 is opened, the flow rate of the fluid may be regulated by the flow rate control device 2024. A pulse vent may be performed, in which purging is performed by repeatedly opening and closing the fourth purge valve 2022. The pulse vent may be performed to purge the supply line 100. For example, the pulse vent may be performed without breaking a vacuum. In this case, exhaustion may be performed so that negative pressure may continuously be applied to continuously maintain a vacuum within the pipe. In an embodiment, the fourth purge valve 2022 may be disposed between the third point P3 and the purge gas supply portion P, and the second purge valve 2012 may be omitted. In this case, the purge pressure sensor 2013 may be disposed between the third point P3 and the fourth purge valve 2022. In addition, the purge pressure sensor 2013 may be disposed between the first purge valve 2011 and the fourth purge valve 2022. In this case, the first regulator 2023 may be disposed between the fourth purge valve 2022 and the purge gas supply portion P. However, this is an example, and the types and disposition of components disposed in the pipe are not limited thereto.

In an embodiment, while a vacuum in the process line 100 is being maintained, the third purge valve 2021 in the purge line 200 may be opened, pressure of the first regulator 2023 may be adjusted (e.g., to be from 10 to 20 psi), and the fourth purge valve 2022 may subsequently be opened. When the purge gas passes through the flow rate control device 2024 (e.g., diameter of 0.2 mm), the flow rate of the purge gas may be reduced and the second purge valve 2012 and the first purge valve 2011 may be opened to allow the purge gas to flow into the process line 100. In this case, purging may be performed by repeating a pulse purge (e.g., opening for 5 seconds and closing for 1 second), using the first purge valve 2011. After the purging is completed, the first purge valve 2011 may be closed, the process line 100 may be exhausted to a vacuum state, a second exhaust valve 3102 may be closed, a vacuum level may be measured using a vacuum sensor (VS) 3002, and after a determined period of time (e.g., 10 minutes), a change in vacuum pressure within the process line 100 may be detected to determine whether the purging is completed.

In an embodiment, a second check valve 2026 may control a fluid flow direction so that the fluid may flow in only one direction to prevent the fluid from flowing backwards. For example, the second check valve 2026 may control the fluid flow direction so that the fluid may flow only in a direction from a front end to a rear end based on the second check valve 2026. The fluid may include a purge gas.

In an embodiment, the first exhaust line 310 may provide a path for the fluid in the supply line 100 to flow to an exhaust portion V to exhaust the fluid in the supply line 100. The first exhaust line 310 may connect the exhaust portion V to the supply line 100 to apply negative pressure to the supply line 100. For example, one end portion of the first exhaust line 310 may be connected to the second point P2 of the supply line 100, and an other end portion may be connected to the exhaust portion V. The exhaust portion V may include a pump that applies negative pressure. For example, the exhaust portion V may create a vacuum state within the line by applying negative pressure to the line. In this case, the exhaust portion V may cause an inside of the line to maintain a vacuum state by continuously applying negative pressure to the line. However, it should be noted that these connection locations are non-limiting examples, and modifications and alterations may be made thereto.

In an embodiment, the first exhaust line 310 may be connected to a first exhaust valve 3101, the second exhaust valve 3102, and a first check valve 3103.

In an embodiment, the first exhaust valve 3101 may control a flow of a fluid flowing through the first exhaust line 310. The first exhaust valve 3101 may be connected to the first exhaust line 310. The first exhaust valve 3101 may selectively open or close the first exhaust line 310. For example, when the first exhaust valve 3101 is opened, the first exhaust line 310 at a front end and a rear end of the first exhaust valve 3101 may be connected to be in fluid communication. In this case, the fluid may flow from the front end of the first exhaust valve 3101 to the rear end of the first exhaust valve 3101. For example, when the first exhaust valve 3101 is closed, the first exhaust line 310 at the front end and the rear end of the first exhaust valve 3101 may be sealed and separated so that the fluid may not flow. In this case, the fluid may not flow from the front end of the first exhaust valve 3101 to the rear end of the first exhaust valve 3101. In other words, the first exhaust line 310 may be separated starting from the first exhaust valve 3101 so that the fluid may not flow through the first exhaust line 310. The first exhaust valve 3101 may be disposed between the second point P2 and the fourth point P4. In this case, the first exhaust valve 3101 may control the flow of the fluid passing through the second point P2 and flowing toward the fourth point P4. However, it should be noted that these connection locations are non-limiting examples, and modifications and alterations may be made thereto.

In an embodiment, the second exhaust valve 3102 may control the flow of the fluid flowing through the first exhaust line 310. When describing the second exhaust valve 3102, in order to avoid duplicate description, the description provided for the first exhaust valve 3101 may apply to a configuration that is substantially identical to the first exhaust valve 3101, to the extent not conflicting with the first exhaust valve 3101. The second exhaust valve 3102 may be disposed between the fourth point P4 and the exhaust portion V. In this case, the second exhaust valve 3102 may control the flow of the fluid passing through the fourth point P4 and flowing through the first exhaust line 310. The second exhaust valve 3102 may be opened and closed independently of the first exhaust valve 3101. However, it should be noted that these connection locations are non-limiting examples, and modifications and alterations may be made thereto.

In an embodiment, the first check valve 3103 may control a fluid flow direction so that the fluid may flow in only one direction to prevent the fluid from flowing backwards. For example, the first check valve 3103 may control the fluid flow direction so that the fluid may flow only in a direction from a front end to a rear end based on the first check valve 3103.

In an embodiment, the second exhaust line 320 may provide a path for the fluid in the purge line 200 to flow to the exhaust portion V to exhaust the fluid in the purge line 200. The second exhaust line 320 may connect the exhaust portion V to the purge line 200 to apply negative pressure to the purge line 200. For example, one end portion of the second exhaust line 320 may be connected to the third point P3 of the purge line 200, and an other end portion may be connected to the exhaust portion V. However, it should be noted that these connection locations are non-limiting examples, and modifications and alterations may be made thereto. In an embodiment, a third exhaust valve 3201 may be connected to the second exhaust line 320.

In an embodiment, the third exhaust valve 3201 may control a flow of the fluid flowing through the second exhaust line 320. The third exhaust valve 3201 may be connected to the second exhaust line 320. The description of the first exhaust valve 3101 and the second exhaust valves 3102 may apply to the description of the third exhaust valve 3201, to the extent not conflicting with the first exhaust valve 3101 and the second exhaust valve 3102. The third exhaust valve 3201 may be connected to a point between the third point P3 and the fourth point P4. In this case, the third exhaust valve 3201 may control the flow of the fluid passing through a section between the third point P3 and the fourth point P4. In other words, the third exhaust valve 3201 may control a state of fluid communication between the third point P3 and the fourth point P4.

In an embodiment, an exhaust pressure sensor (not shown) may detect pressure within the second exhaust line 320. For example, the exhaust pressure sensor may be connected to the second exhaust line 320. For example, the exhaust pressure sensor may detect whether an inside of the second exhaust line 320 is in a vacuum state. In an embodiment, an exhaust pressure sensor may be connected to a point between the third exhaust valve 3201 and the fourth point P4. The exhaust pressure sensor may detect pressure in a section between the third exhaust valve 3201 and the fourth point P4. However, it should be noted that these connection locations are non-limiting examples, and modifications and alterations may be made thereto.

Referring to FIG. 2, a conventional gas supply system may include a supply line 700, a purge line 800, and an exhaust line 900. When describing the conventional gas supply system of FIG. 2, in order to avoid duplicate description, the description provided with reference to FIG. 1 may apply to a configuration that is substantially identical or similar to the gas supply system 1 of FIG. 1.

The supply line 700 of the conventional gas supply system may be connected to a supply pressure sensor 7016, a first supply valve 7011, a second supply valve 7012, a second regulator 7013, and a supply filter 7015. The purge line 800 of the conventional gas supply system may be connected to a first purge valve 8011, a second purge valve 8012, a third purge valve 8021, a purge pressure sensor 8013, a fourth purge valve 8022, and a second check valve 8026. The exhaust line 900 of the conventional gas supply system may be connected to a first exhaust valve 9101 and a second exhaust valve 9102. In an embodiment, the conventional gas supply system may reduce concentration of hazardous gases within the supply line 700 by diluting gas present within a pipe by injecting a purge gas into the supply line 700 through the purge line 800 and by removing gas within the supply line 700 through the exhaust line 900. However, when the conventional gas supply system pressurizes the purge gas into the supply line 700, moisture among impurities contained in the purge gas may flow into the supply line 700 and be absorbed into the pipe or components of the conventional gas supply system to react with an oxidizing gas or a corrosive gas, thereby causing corrosion or a failure.

In contrast, the gas supply system 1 according to an embodiment may be configured so that there is no stagnant section when a fluid flows between the first purge valve 2011 and the first exhaust valve 3101. For example, the stagnant section may include a component involved in a flow of the fluid, such as a valve that controls the flow of the fluid, a regulator that controls pressure of the fluid, or the flow rate control device 2024 that controls the flow of the fluid. For example, when the gas supply system 1 is configured so that there is no stagnant section for the fluid flowing between the first purge valve 2011 and the first exhaust valve 3101, a purge effect in a section between the first purge valve 2011 and the first exhaust valve 3101 may be maximized.

The conventional gas supply system may create a vacuum between the first purge valve 8011 and the second purge valve 8012 to prevent the purge gas from being mixed into a processing gas when the processing gas is supplied. In this case, as the usage period of the conventional gas supply system increases, a trace amount of oxygen and moisture may flow into a pipe between the first purge valve 8011 and the second purge valve 8012. In addition, a trace amount of purge gas may flow into the supply line 700 and the processing gas and the purge gas may thus mix together. For example, when a trace amount of oxygen and moisture that has flowed into the pipe between the first purge valve 8011 and the second purge valve 8012 is mixed with the purge gas when the purge gas is injected and flows into the supply line 700, corrosion of the pipe and/or a failure of components may occur.

In contrast, the gas supply system 1 may vent, through the third exhaust valve 3201, a trace amount of purge gas, oxygen, or moisture present in the purge line 200 before injecting the purge gas. In this case, by blocking an inflow of oxygen or moisture into the supply line 100, corrosion of the pipe and/or a failure of components may be reduced or prevented. It should be noted that the differences between the gas supply system 1 and the conventional gas supply system described herein are non-limiting examples.

It should be noted that the connection relationship of the individual supply line 100 described herein is an example, and one of ordinary skill in the art may change the connection relationship according to an installation location of the gas supply system 1 and other environments. It should also be noted that the presence or absence, connection location, number, and types of valves and sensors connected to the supply line 100 may be changed.

The gas supply system 1 may purge the supply line 100, using a gas supply method before supplying a processing gas to the supply line 100 after replacing a gas container. A gas supply method according to an embodiment may proceed from an initial state in which all valves are closed. In the gas supply method, an operation of opening the second exhaust valve 3102 and checking, using a pressure sensor, whether there is an abnormality in a vacuum pump may be performed. Thereafter, an operation of opening the first exhaust valve 3101 and the second supply valve 1012 and exhausting may be performed. Thereafter, an operation of opening the third exhaust valve 3201 and the second purge valve 2012 and exhausting may be performed. The order of the operation of opening the first exhaust valve 3101 and the second supply valve 1012 and exhausting and the operation of opening the third exhaust valve 3201 and the second purge valve 2012 and exhausting may be performed interchangeably. Thereafter, a pulse vent may be performed, in which the third exhaust valve 3201 is closed, the first purge valve 2022 is opened, and the fourth purge valve 2022 is repeatedly opened and closed.

In an embodiment, an inflow of gas from the purge line 200 into the supply line 100 may be reduced or prevented by maintaining pressure between the second purge valve 2012 and the first purge valve 2011 to be lower than pressure within the supply line 100. In other words, since gas flows from a place of high pressure to a place of low pressure, impurities such as oxygen or moisture may not flow from a pipe between the second purge valve 2012 and the first purge valve 2011, a pressure within which is relatively low compared to the supply line 100, toward the supply line 100 having a relatively high pressure, but flow from the supply line 100 into the pipe between the second purge valve 2012 and the first purge valve 2011. Accordingly, while negative pressure is maintained in the pipe between the second purge valve 2012 and the first purge valve 2011, a gas capable of reacting with an oxidizing gas may flow into the pipe between the second purge valve 2012 and the first purge valve 2011, thereby causing corrosion of the pipe and components. In addition, when purging the first purge valve 2011 and the supply line 100, the purge gas may be mixed with the moisture, oxygen gas, and the like that have flowed therein and may flow into the supply line 100 to react with each other. For example, gases that react with moisture or oxygen gas may include hydrogen fluoride (HF), hydrogen chloride (HCl), or hydrogen bromide (HBr). In this case, corrosion of the pipe and components may occur. To prevent this, both sides of the first purge valve 2011 may be exhausted. In other words, the gas supply method may open the second purge valve 2012 while the first purge valve 2011 is closed and exhaust both sides of the first purge valve 2011 through the second exhaust line 320. In addition, the gas supply method may open the second exhaust valve 3102, the first exhaust valve 3101, and the second supply valve 1012 to exhaust the supply line 100.

In an embodiment, nitrogen gas or a trace amount of moisture may be purged through a viscous purge. For example, the viscous purge may refer to a purge using a viscous flow. The gas supply method may effectively remove moisture molecules or oxidizing gas within the pipe by causing, through the viscous purge, purge gas molecules to collide with the moisture molecules or the oxidizing gas within the pipe. Furthermore, the gas supply method may discharge moisture and the purge gas together by maintaining the pressure within the pipe to be lower than saturated vapor to vaporize moisture mixed in the purge gas or liquid moisture within the pipe during the viscous purge.

In an embodiment, the gas supply method may control a pressure and a flow rate of the purge gas when supplying the purge gas. For example, the gas supply method may supply the purge gas while controlling the pressure and the flow rate of the purge gas so that the pressure and flow rate of the purge gas may be within a determined range. Here, the gas supply method may control the pressure and the flow rate of the purge gas, using a plurality of pressure regulating components and flow rate regulating components provided in the purge line. Moisture may be efficiently removed in a short period of time by increasing a number of cycles of supply/cutoff of the purge gas and a purging time. A lower limit of the pressure of the purge gas supplied by the gas supply method may be a pressure and a flow rate at which the viscous purge may be performed. The pressure and the flow rate for the purge gas to flow in a viscous flow may be determined based on a pipe diameter. Lower limit values of the pressure and the flow rate may be determined by a Knudsen number K. For example, the Knudsen number K may be a mean free distance of a gas divided by a representative length of an object (e.g., the diameter of the pipe). When the Knudsen number K is less than 1, a number of collisions between the purge gas molecules may increase. The lower limit values of the pressure and the flow rate may be greater than or equal to a pressure and a flow rate that causes the Knudsen number K according to a predetermined diameter of the pipe to be less than 1. Upper limit values of the pressure and the flow rate of the purge gas supplied by the gas supply method may be less than or equal to the saturated vapor pressure of water within the pipe to allow evaporation of water molecules adsorbed on the inner wall surface of the pipe. For example, the type of gas for the viscous purge may include at least one of helium, neon, argon, or nitrogen. However, it should be noted that the types of purge gas are non-limiting examples.

The gas supply method may include an operation of opening a second exhaust valve, an operation of continuously applying negative pressure by an exhaust portion, an operation of opening a first exhaust valve and a second supply valve, an operation of opening a third exhaust valve and a second purge valve, an operation of closing the third exhaust valve and opening a first purge valve, and an operation of repeatedly opening and closing a fourth purge valve. However, it should be noted that each of the operations may be omitted or performed repeatedly and may be performed in a different order.

In an embodiment, the gas supply method may be performed with the gas container G closed. The gas supply method may maintain the pressure within the pipe to be less than or equal to the saturated vapor pressure by applying negative pressure through the exhaust portion V to create a vacuum state in a space within a line and subsequently supplying a trace amount of the purge gas. In this case, the supply line 100 may be purged by repeatedly supplying a trace amount of the purge gas. In addition, moisture in the purge gas may be vaporized and discharged simultaneously with the injection of the purge gas.

In an embodiment, the gas supply method may further include an operation of detecting, using the exhaust pressure sensor 4002, whether there is a vacuum, after an operation of closing the second exhaust valve 3102. The gas supply method may include an operation of detecting, using the exhaust pressure sensor 4002, whether there is a vacuum, and closing the first exhaust valve 3101 or all valves when a pressure change range is less than or equal to a preset value for a determined period of time. When the pressure change range is less than or equal to the preset value for a determined period of time, purging may be determined to be complete.

Although the examples have been described with reference to the limited number of drawings, it will be apparent to one of ordinary skill in the art that various technical modifications and variations may be made in the examples without departing from the spirit and scope of the claims and their equivalents. For example, suitable results may be achieved if the described techniques are performed in a different order, and/or if components in a described system, architecture, device, or circuit are combined in a different manner and/or replaced or supplemented by other components or their equivalents.

Therefore, other implementations, other examples, and equivalents to the claims are also within the scope of the following claims.

What is claimed is:

1. A gas supply system comprising:
a supply line configured to connect a gas container to a process object;
a purge line connected to a first point of the supply line and connected to a purge gas supply portion configured to supply a purge gas;
a first exhaust line connected to a second point of the supply line and connecting the supply line to an exhaust portion configured to apply negative pressure; and
a second exhaust line connected to a third point of the purge line and connecting the purge line to a fourth point of the first exhaust line.

2. The gas supply system of claim 1, wherein
the first point of the supply line is closer to the gas container than the second point is, and
the supply line is connected to:
a supply pressure sensor configured to detect a pressure within the supply line; and
a first supply valve configured to control a flow of a fluid flowing through the supply line.

3. The gas supply system of claim 1, wherein the purge line is connected to:
a first purge valve disposed to a point between the first point and the third point and configured to control a flow of a fluid flowing through the purge line;
a second purge valve disposed between the first purge valve and the third point and configured to control the flow of the fluid flowing through the purge line;
a purge pressure sensor disposed between the first purge valve and the second purge valve and configured to detect a pressure within the purge line;
a first regulator disposed between the third point and the purge gas supply portion and configured to control the pressure within the purge line; and
a flow rate control device disposed between the first regulator and the third point.

4. The gas supply system of claim 1, wherein
the first exhaust line is connected to:
a first exhaust valve disposed between the second point and the fourth point; and
a second exhaust valve disposed between the fourth point and the exhaust portion, and
the second exhaust line is connected to:
a third exhaust valve configured to control gas supply; and
an exhaust pressure sensor disposed between the third exhaust valve and the fourth point and configured to detect a pressure within a line.

5. The gas supply system of claim 1, wherein the purge line is connected to:
a first purge valve disposed to a point between the first point and the third point and configured to control a flow of a fluid flowing through the purge line;
a fourth purge valve disposed between the third point and the purge gas supply portion and configured to control the flow of the fluid flowing through the purge line;
a purge pressure sensor disposed between the first purge valve and the fourth purge valve and configured to detect a pressure within the purge line;
a first regulator disposed between the fourth purge valve and the purge gas supply portion and configured to control the pressure within the purge line; and
a flow rate control device disposed between the first regulator and the fourth purge valve.

6. The gas supply system of claim 1, wherein the supply line is further connected to:
a second regulator configured to control a pressure of the supply line.

7. The gas supply system of claim 1, wherein the supply line is further connected to:
a second supply valve configured to control a flow within the supply line.

8. The gas supply system of claim 1, wherein the supply line is further connected to a front end of a supply filter.

9. The gas supply system of claim 1, wherein the first exhaust line is further connected to a first exhaust valve disposed between the second point and the fourth point.

10. The gas supply system of claim 3, wherein the purge line is further connected to a fourth purge valve connected to a rear end of the flow rate control device.

11. A gas supply method using a gas supply system according to claim 1, the gas supply method comprising:
opening a second exhaust valve;
continuously applying, by an exhaust portion, negative pressure;
opening a first exhaust valve and a second supply valve;
opening a third exhaust valve and a second purge valve;
closing the third exhaust valve and opening a first purge valve; and
repeatedly opening and closing a fourth purge valve.

12. The gas supply method of claim 11, further comprising:
after opening the second exhaust valve,
detecting, using a exhaust pressure sensor, whether there is a vacuum.

13. The gas supply method of claim 11, further comprising:
detecting, using exhaust pressure sensor, whether there is a vacuum; and
closing the first exhaust valve or all valves, when a pressure change range is less than or equal to a preset value for a determined period of time.

14. The gas supply method of claim 11, further comprising:
venting a second exhaust line, with the first purge valve closed.

15. The gas supply method of claim 11, further comprising:
venting a first exhaust line.

16. A gas supply method using a gas supply system according to claim 1, the gas supply method comprising:
providing the gas supply system with all valves closed;
venting a first exhaust line and a supply line while a first supply valve, a fourth purge valve, and a first purge valve are closed;
exhausting a second exhaust line and a purge line to a vacuum state; and
closing the second exhaust line and performing a pulse vent, using a flow rate control device and the fourth purge valve of the purge line, between a first pressure and a second pressure.

17. The gas supply method of claim 16, wherein
the first pressure is a pressure that causes a Knudsen number according to a diameter of a pipe to be less than 1, and
the second pressure is a pressure less than or equal to a saturated vapor pressure of water in the pipe to cause water molecules within the pipe to evaporate.
